(19) United States
(12) Patent Application Publication
(10) Pub. No.: US 2024/0111004 A1
(43) Pub. Date: Apr. 4, 2024

(54) HALL EFFECT SENSOR ASSEMBLY FOR USE WITH GAME CONTROLLER JOYSTICKS

(71) Applicant: Panda Hardware LLC, Spring House, PA (US)

(72) Inventor: Matthew Samperi, Lansdale, PA (US)

(21) Appl. No.: 17/958,833

(22) Filed: Oct. 3, 2022

(51) Int. Cl. G01R 33/07; A63F 13/21; A63F 13/24

(52) U.S. Cl. CPC G01R 33/075; A63F 13/21; A63F 13/24

(57) ABSTRACT

A hall effect sensor assembly for use with a game controller joystick. The assembly includes a housing. Inside the housing is a magnet, a PCB, and a hall effect sensor. The hall effect sensor is connected to the PCB. Signal communication structure, such as through pins, is also connected to the PCB. The signal communication structure extends from the housing and is connectable to the main PCB of a game controller. The magnet rotates in the housing, and the PCB uses the hall effect sensor to sense a rotational position of the magnet. The PCB communicates the rotational position of the magnet to the main game controller PCB via the signal communication structure.

### BACKGROUND

The present invention generally relates to game controller joysticks, and more specifically relates to a novel hall effect sensor assembly for use with game controller joysticks.

As shown in FIG. 1, most modern game controllers that include a joystick provide that the joystick 10 comprises a stick 12 which extends from a stickbox 14. A stick cap (not shown) typically covers the stick 12 and this is where the thumb of a user makes contact. The stickbox 14 holds the stick 12 generally in place and guides the stick 12 in both the x and y directions while the stick is being moved or pivoted by a user. Actuating arms 16 extend out of two of the four sides of the stickbox 14, wherein one actuating arm relates to movement of the stick in the x-direction while the other actuating arm relates to movement of the stick in the y-direction (FIG. 1 shows one of the actuating arms 16).

As shown in FIG. 2, many game controller joysticks provide that rotary analog potentiometers 18 receive the actuating arms 16 and sense the position of the stick 12. As shown, typically two potentiometers 18 are provided—one to detect motion in the x-direction, and another to detect motion in the y-direction. The potentiometers 18 detect linear motion by effectively converting the motion into an electrical signal. Both potentiometers 18 include game controller PCB engaging structure 20, typically in the form of a plurality of through pins, which engage and electrically contact the game controller PCB and provide the electrical signal thereto for further processing by the game controller PCB.

As shown in FIG. 3, the way these potentiometers work is they use a wiper 22 that is attached to the stick 12, and the wiper drags along a resistive material 24 (such as a wire or a film) to create a detectable change in position. Specifically, as the wiper 22 is dragged along the resistive material 24, the resistance of the potentiometer changes, causing a voltage change in the overall circuit (i.e., at the terminals at the bottom of FIG. 3).

These devices are reliable when there is strong electrical contact between the wiper 22 and the resistive material 24. However, over time, physical and chemical damage can occur which dramatically shortens the lifespan of the potentiometer. This type of damage is a common source of “drift” of the game controller. Joystick drifting is when the joystick movement effectively has a mind of its own. Drift is most noticeable and detrimental in games where accuracy is essential, such as in shooter and racing games.

As shown in FIG. 4, in an attempt to circumvent drift, some game controllers use hall effect sensor assemblies 26 instead of potentiometers to detect the position and movement of the stick 12 of a joystick. As shown, these game controllers provide that a small magnet 28 is attached to the bottom of the stick 12. A hall effect sensor 30 is beneath the magnet 28, mounted directly to a main printed circuit board (PCB) 32. As the stick 12 is pivoted by a user, the magnet 28 pivots (in an arc-like motion) above the hall effect sensor 30, and the hall effect sensor 30 detects a change in the position of the magnet 28 (five different representative positions of the magnet 28 are shown in FIG. 4, with the neutral position being in the middle at the bottom, indicated with reference numeral 34). As the stick 12 is pivoted, and the magnet 28 pivots away from the joystick's neutral position 34, the distance between the magnet 28 and the hall effect sensor 30 becomes greater, giving the sensor 30 a weaker and less accurate signal compared to when the stick 12 is in the neutral position 34. As shown in FIG. 4, there is a much longer distance (indicated with reference numeral 36) between the hall effect sensor 30 and the furthest magnet position than there is between the hall effect sensor 30 and the closest magnet position (i.e., the stick's neutral position 34) (that shorter distance is indicated with reference numeral 38).

In general, hall effect sensors generate signals from contactless motion. When employed in a game controller in place of potentiometer technology (which relies on friction), use of hall effect sensor technology in a game controller can effectively lengthen the lifespan of an analog joystick to the lifespan of the integrated circuits within the hall effect sensor itself, which can theoretically last forever. Using contactless technology not only extends the life cycle of the game controller but also provides for more resistance to, for example, concussive forces and water intrusion. Additionally, hall effect sensors can be digital or analog, giving a game controller designer greater control and access to precision data related not only to the angle of the shaft of the joystick but also possible error states which could be used to indicate problems before the problems become an issue.

Hall effect sensors use a different mounting layout than a standard joystick potentiometer. More specifically, as used in a game controller, while a conventional hall effect sensor mounts using four (4) surface mount technology (SMT) pads (SMT pads are shown in FIG. 6), a conventional potentiometer mounts using through hole pins (see FIG. 2). As a result, game controller manufacturers would need to redesign the circuit boards of their game controllers in order to utilize hall effect sensor technology in place of potentiometer technology. Unfortunately, this requires substantial expense.

Furthermore, the magnet 28 that is connected to the bottom of the stick 12 is not part of the same assembly as the assembly that contains the hall effect sensor 30. As a result, this causes a variation in alignment between the magnet and the corresponding hall effect sensor in every single controller and adds another variable in mass production. In other words, basically one game controller may have a better alignment of the hall effect sensors and the corresponding magnets than another game controller with the same design. Therefore, one game controller may have a more accurate joystick than another game controller, despite both having been assembled in the same assembly run.

### SUMMARY

One object of an embodiment of the present invention is to provide a game controller that employs an improved hall effect sensor design.

Another object of an embodiment of the present invention is to provide a game controller that includes an all-in-one hall effect sensor assembly.

Another object of an embodiment of the present invention is to provide a hall effect sensor design implementation that provides for drop-in replacement of existing joystick potentiometers.

Still another object of an embodiment of the present invention is to provide a game controller that employs a hall effect sensor design that comprises a diametrically polarized magnet that spins axially directly above a hall effect sensor.

Briefly, an embodiment of the present invention provides a hall effect sensor assembly for use with a game controller joystick. The hall effect sensor assembly includes a housing, and inside the housing is a magnet, a PCB, and a hall effect sensor. The hall effect sensor is connected to the PCB. Signal communication structure, such as through pins, is also connected to the PCB. The signal communication structure extends from the housing and is connectable to the main PCB of a game controller. The magnet rotates in the housing, and the PCB uses the hall effect sensor to sense a rotational position of the magnet. The PCB communicates the rotational position of the magnet to the main game controller PCB via the signal communication structure.

### BRIEF DESCRIPTION OF THE DRAWINGS

The organization and manner of the structure and operation of the invention, together with further objects and advantages thereof, may best be understood by reference to the following description taken in connection with the accompanying drawings wherein like reference numerals identify like elements in which:

FIG. 1 is a perspective view of a conventional stickbox of a joystick of a game controller;

FIG. 2 is a perspective view of a conventional joystick of a game controller, where potentiometers are engaged with the stickbox of FIG. 1;

FIG. 3 is a schematic view which shows generally how the potentiometers of FIG. 2 work;

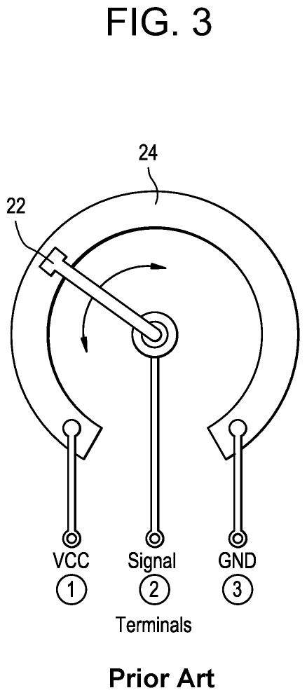

FIG. 4 is a side view of a conventional joystick of a game controller, where hall effect sensor assemblies are engaged with the stickbox of FIG. 1;

FIG. 5 is a perspective view of a hall effect sensor assembly that is in accordance with an embodiment of the present invention;

FIG. 6 shows a diametrically polarized magnet and corresponding hall effect sensor that is contained within the assembly shown in FIG. 5;

FIG. 7 is a cross-sectional view that shows the assembly of FIG. 5 engaged with the actuating arm of the stickbox shown in FIG. 1; and

FIG. 8 is a side view of a game controller joystick that is in accordance with an embodiment of the present invention, wherein a hall effect sensor assembly as shown in FIG. 7 is engaged with both actuating arms of the stickbox shown in FIG. 1.

### DESCRIPTION

While this invention may be susceptible to embodiment in different forms, there is shown in the drawings and will be described herein in detail, a specific embodiment with the understanding that the present disclosure is to be considered an exemplification of the principles of the invention and is not intended to limit the invention to that as illustrated.

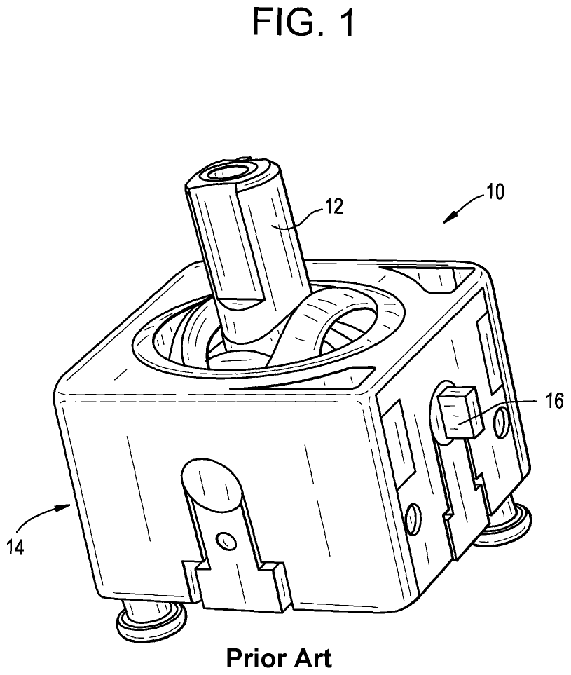

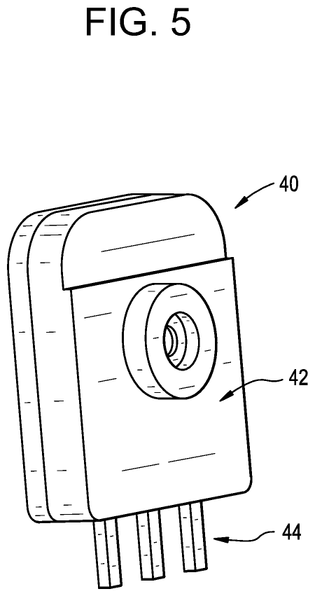

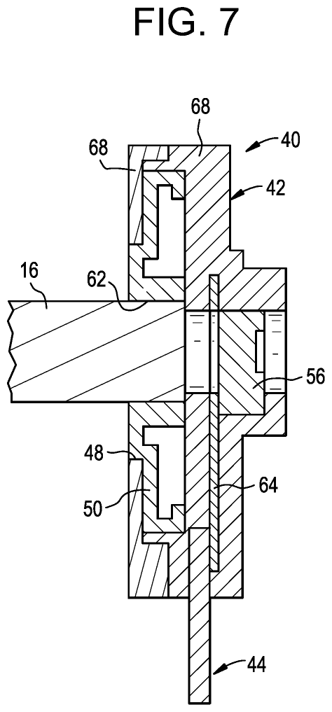

FIG. 5 is a perspective view of a hall effect sensor assembly 40 that is in accordance with an embodiment of the present invention. As shown, the hall effect sensor assembly 40 includes a housing 42 and signal communication structure 44 (preferably through hole pins, or SMT pads) which extends from the housing. The signal communication structure 44 is preferably configured to connect to the main PCB 46 of a game controller (see FIG. 7). The housing 42 preferably includes a hole 48 (shown in FIG. 7) which, as will be described in more detail hereinbelow, is configured to receive the stickbox potentiometer actuating arm 16 of a conventional game controller stickbox 14 (see FIG. 1).

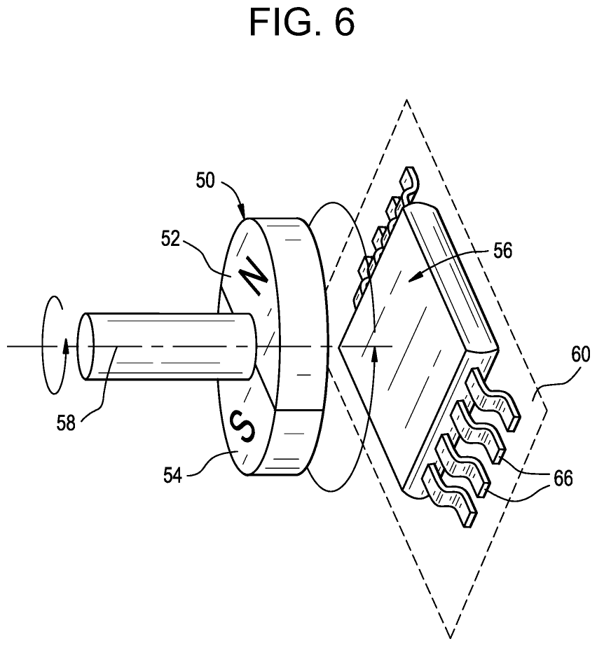

FIG. 6 shows a diametrically polarized magnet (or magnet assembly) 50 (i.e., one section 52 having one polarity (i.e., N), and the other section 54 having the opposite polarity (i.e., S)) and a corresponding hall effect sensor 56 that is preferably contained within the housing 42 shown in FIG. 5. The magnet 50 is configured to rotate adjacent the hall effect sensor 56. As shown in FIG. 6, the magnet 50 rotates along an axis 58 that is perpendicular to a plane 60 on which the hall effect sensor 56 sits. During operation of the joystick, the magnet 50 does not move closer to or further from the hall effect sensor 56. Instead, the magnet 50 rotates axially (along its center axis 58) adjacent the hall effect sensor 56 and stays the same distance from the hall effect sensor 56 regardless of the stick's position.

As shown in FIG. 7, the stickbox potentiometer actuating arm 16 (as shown in FIG. 1) extends into the hole 48 in the housing and engages the diametrically polarized magnet 50. Specifically, the magnet or magnet assembly 50 preferably includes a receptacle 62, such as a rectangular hole, in its center which receives the stickbox potentiometer actuating arm 16.

As shown, the assembly 40 also includes an internal assembly PCB 64 within the housing 42, and the signal communication structure (such as three through pins) 44 is connected to the internal assembly PCB 64. The hall effect sensor 56 is also connected, such as surface mounted via SMT pads 66 (see FIG. 6), to the internal assembly PCB 64. As shown in FIG. 7, the housing 42 may comprise multiple pieces (such as two part, two shot molded, over-molded, or another method of manufacturing assembly) that connect together to form a single housing that contains the diametrically polarized magnet 50, the hall effect sensor 56, and the internal assembly PCB 64.

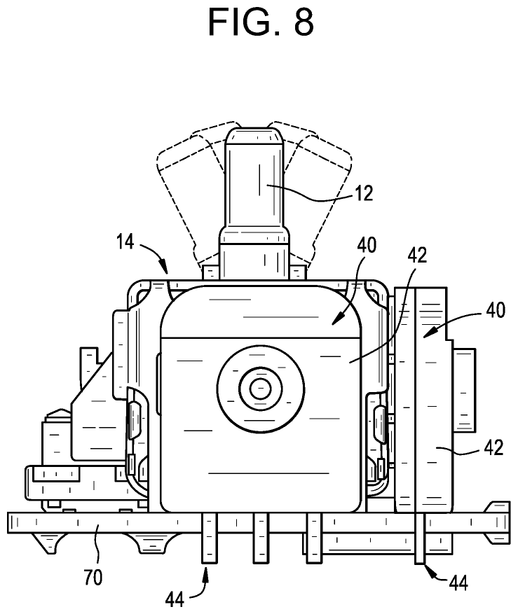

During operation of the joystick, the magnet 50 rotates adjacent the hall effect sensor 56 within the housing 42, as shown in FIG. 6. As shown in FIGS. 5, 7 and 8, the signal communication structure 44 extends from the housing 42 and, as shown in FIG. 8, connects to the game controller PCB 70. Rotation of the potentiometer actuating arm 16 causes the diametrically polarized magnet 50 to also rotate (axially, adjacent to the hall effect sensor 56 inside the housing 42). The PCB 64 uses the hall effect sensor 50 to sense the rotational position of the magnet 50 and outputs this information (as a digital signal or analog voltage) through the signal communication structure 44 to the game controller PCB 70 (see FIG. 8).

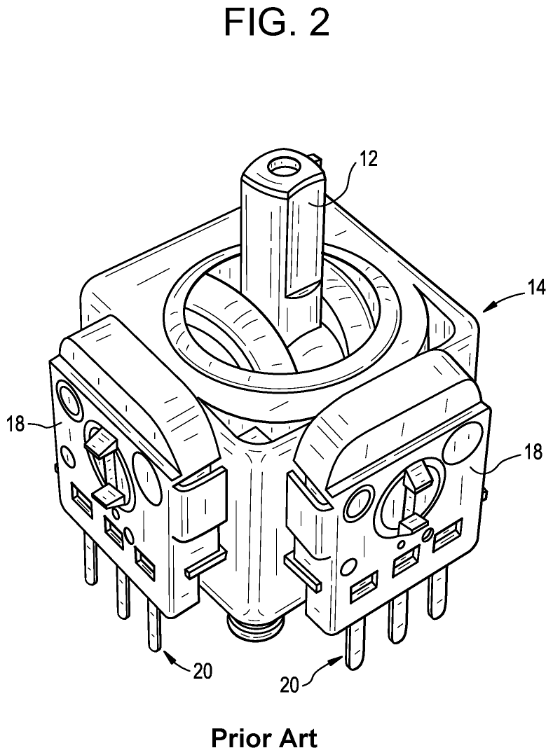

The hall effect sensor assembly 40 shown in FIG. 5 is configured to be a drop-in replacement for existing joystick potentiometers 18 (as shown in FIG. 2), allowing for consumers or manufacturers to use this design with their existing controllers. The assembly 40 maintains the same form and function of potentiometers 18, but utilizes a hall effect sensor 56 and magnet 50, instead of a potentiometer, to output a digital or analog signal without risk of decay. The hall effect sensor assembly 40 can be configured such that the hall effect sensor 56 and the internal PCB 64 can be collectively reprogrammed via the signal communication structure 44.

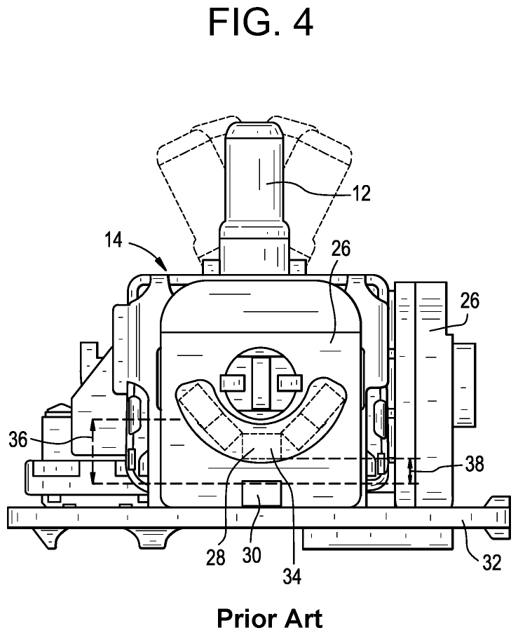

As shown in FIGS. 6 and 7, the magnet 50 of the hall effect sensor assembly 40 is always the same distance from the hall effect sensor 56, so the design always provides a constant signal strength. The magnet 50 is also able to be located closer to the hall effect sensor 56 (compared to the design shown in FIG. 4) by virtue of the design and therefore can provide a stronger signal to the hall effect sensor 56, providing more accurate and reliable joystick position data to the controller. Since the magnet 50 and the hall effect sensor 56 are part of the same subassembly within the same housing 42, the position of the magnet 50 in relation to the hall effect sensor 56 can be controlled to a much higher degree in mass production and assembly. This allows for consistency across all controllers in which this sensor is installed.

The hall effect sensor assembly 40 also provides the same benefits over potentiometers as current hall effect sensor implementations by having a theoretical infinite electrical life cycle through contactless motion.

The hall effect sensor assembly 40 (and specifically the PCB 64) can be configured to send a digital signal rather than an analog voltage signal which creates a number of benefits for signal integrity and data calibration which can be done on the sensor or controller side of the controller assembly.

The hall effect sensor assembly 40 allows for the internal PCB 64 and hall effect sensor 56 to be able to be collectively programmed differently for compatibility with different controllers and joysticks.

While a specific embodiment of the invention has been shown and described, it is envisioned that those skilled in the art may devise various modifications without departing from the spirit and scope of the present invention.

What is claimed is:

1. A hall effect sensor assembly for use with a game controller joystick, said hall effect sensor assembly comprising:
a housing; a magnet inside the housing;
a PCB inside the housing; a hall effect sensor inside the housing and connected to the PCB; and
signal communication structure connected to the PCB and extending from the housing, wherein the magnet is configured to rotate adjacent to the hall effect sensor within the housing such that a distance between the magnet and the hall effect sensor remains constant when the magnet is rotated, wherein the hall effect sensor is configured to sense a rotational position of the magnet, and wherein the PCB is configured to communicate the rotational position of the magnet via the signal communication structure.

2. The hall effect sensor assembly as recited in claim 1, wherein the housing comprises a hole configured to receive an actuating arm of a joystick.

3. The effect sensor assembly as recited in claim 1, wherein the magnet is diametrically polarized.

4. The effect sensor assembly as recited in claim 1, wherein half the magnet is polarized with one polarity, and another half of the magnet is polarized with the opposite polarity.

5. The effect sensor assembly as recited in claim 1, wherein the magnet is configured to rotate along an axis that is perpendicular to a plane on which the hall effect sensor sits.

6. (canceled)

7. The hall effect sensor assembly as recited in claim 1, wherein the magnet is configured to rotate axially along its center axis adjacent the hall effect sensor and stays the same distance from the hall effect sensor regardless of a position of a game controller joystick for which the hall effect sensor assembly is employed.

8. The hall effect sensor assembly as recited in claim 1, wherein the magnet is round.

9. The hall effect sensor assembly as recited in claim 1, wherein the magnet comprises a receptacle configured to receive an actuating arm of a joystick.

10. The hall effect sensor assembly as recited in claim 1, wherein the housing comprises a hole configured to receive an actuating arm of a joystick, and wherein the magnet comprises a receptacle configured to receive the actuating arm.

11. The hall effect sensor assembly as recited in claim 1, wherein the signal communication structure comprises pins.

12. The hall effect sensor assembly as recited in claim 1, wherein the signal communication structure comprises three through hole pins.

13. (canceled)

14. The game controller joystick comprising a plurality of hall effect sensor assemblies, wherein each hall effect sensor assembly of said plurality of hall effect sensor assemblies is as recited in claim 1.
